(19) United States
(12) Patent Application Publication
(10) Pub. No.: US 2026/0293253 A1
(43) Pub. Date: Sep. 24, 2026

(54) SILICON CARBIDE SUBSTRATE, SILICON CARBIDE EPITAXIAL SUBSTRATE, AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventor: Tsubasa HONKE, Osaka (JP)

(73) Assignee: SUMITOMO ELECTRIC INDUSTRIES, LTD., Osaka (JP)

(21) Appl. No.: 19/100,592

(22) PCT Filed: Jun. 21, 2023
(86) PCT No.: PCT/JP2023/022960

§ 371 Date: Feb. 3, 2025

(30) Foreign Application Priority Data
Aug. 8, 2022 (JP) 2022-126501

(51) Int. Cl. H10D 62/832; H10D 12/00; H10D 12/01; H10D 30/01; H10D 30/66

(52) U.S. Cl. CPC H10D 62/8325; H10D 12/038; H10D 30/0297; H10D 12/481; H10D 30/668

(57) ABSTRACT

A silicon carbide substrate has a main surface. The main surface is constituted of an outer peripheral portion within 3 mm from an outer peripheral edge of the main surface and a central portion surrounded by the outer peripheral portion. In any square region in the central portion, an arithmetic mean height defined as Sa is 0.1 nm or less and a skewness defined as Ssk is 0 or more. A length of each side of the square region is 250 μm.

### TECHNICAL FIELD

The present disclosure relates to a silicon carbide substrate, a silicon carbide epitaxial substrate, and a method of manufacturing a silicon carbide semiconductor device. The present application claims priority based on Japanese Patent Application No. 2022-126501 filed on Aug. 8, 2022. The entire contents of the Japanese Patent Application are incorporated herein by reference.

### BACKGROUND ART

WO 2016/063632 (PTL 1) describes a silicon carbide substrate having a main surface with a surface roughness of 0.1 nm or less.

### CITATION LIST

### Patent Literature

PTL 1: WO 2016/063632

### SUMMARY OF INVENTION

A silicon carbide substrate according to the present disclosure includes a main surface. The main surface is constituted of an outer peripheral portion within 3 mm from an outer peripheral edge of the main surface and a central portion surrounded by the outer peripheral portion. In any square region in the central portion, an arithmetic mean height defined as Sa is 0.1 nm or less and a skewness defined as Ssk is 0 or more. A length of each side of the square region is 250 μm.

### BRIEF DESCRIPTION OF DRAWINGS

FIG. 1 is a schematic plan view showing a configuration of a silicon carbide substrate according to the present embodiment.

FIG. 2 is a schematic cross sectional view along a line II-II of FIG. 1.

FIG. 3 is a schematic plan view showing a configuration of a region III in FIG. 1.

FIG. 4 is a schematic cross sectional view along a line IV-IV of FIG. 3.

FIG. 5 is a schematic diagram showing a step of performing chemical mechanical polishing onto the silicon carbide substrate.

FIG. 6 is a flowchart schematically showing a method of manufacturing a silicon carbide semiconductor device according to the present embodiment.

FIG. 7 is a schematic cross sectional view showing a configuration of a silicon carbide epitaxial substrate according to the present embodiment.

FIG. 8 is a schematic cross sectional view showing a step of forming a body region.

FIG. 9 is a schematic cross sectional view showing a step of forming a source region.

FIG. 10 is a schematic cross sectional view showing a step of forming a trench in a third main surface of a silicon carbide epitaxial layer.

FIG. 11 is a schematic cross sectional view showing a step of forming a gate insulating film.

FIG. 12 is a schematic cross sectional view showing a step of forming a gate electrode and an interlayer insulating film.

FIG. 13 is a schematic cross sectional view showing a configuration of the silicon carbide semiconductor device according to the present embodiment.

FIG. 14 is a diagram showing a relation between Sa and Ssk.

FIG. 15 is a diagram showing a relation between Sa and a breakdown voltage failure ratio.

### DETAILED DESCRIPTION

### Problem to be Solved by the Present Disclosure

An object of the present disclosure is to improve yield of a silicon carbide semiconductor device.

### Advantageous Effect of the Present Disclosure

According to the present disclosure, it is possible to improve yield of a silicon carbide semiconductor device.

### DESCRIPTION OF EMBODIMENTS

First, embodiments of the present disclosure will be listed and described.
(1) A silicon carbide substrate 100 according to the present disclosure includes a main surface 1. Main surface 1 is constituted of an outer peripheral portion 12 within 3 mm from an outer peripheral edge 4 of main surface 1 and a central portion 10 surrounded by outer peripheral portion 12. In any square region 5 in central portion 10, an arithmetic mean height defined as Sa is 0.1 nm or less and a skewness defined as Ssk is 0 or more. A length of each side of square region 5 is 250 μm.
(2) In silicon carbide substrate 100 according to (1), the skewness defined as Ssk may be 0.4 or less.
(3) In silicon carbide substrate 100 according to (1), the skewness defined as Ssk may be 0.3 or less.
(4) In silicon carbide substrate 100 according to any one of (1) to (3), the arithmetic average height defined as Sa may be 0.06 nm or more.
(5) In silicon carbide substrate 100 according to (1), the arithmetic average height defined as Sa may be 0.06 nm or more and the skewness defined as Ssk may be 0.3 or less.
(6) In silicon carbide substrate 100 according to any one of (1) to (5), a maximum diameter of the main surface may be 150 mm or more.
(7) A silicon carbide epitaxial substrate 200 according to the present disclosure includes: silicon carbide substrate 100 according to any one of (1) to (6); and a silicon carbide epitaxial layer 20 provided on silicon carbide substrate 100.
(8) A method of manufacturing a silicon carbide semiconductor device 400 according to the present disclosure includes the following steps. Silicon carbide epitaxial substrate 200 according to (7) is prepared. Silicon carbide epitaxial substrate 200 is processed.

### DETAILS OF EMBODIMENTS OF THE PRESENT DISCLOSURE

The following describes an embodiment of the present disclosure with reference to figures. It should be noted that in the below-mentioned figures, the same or corresponding portions are given the same reference characters and are not described repeatedly. Regarding crystallographic indications in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

### <Silicon Carbide Substrate>

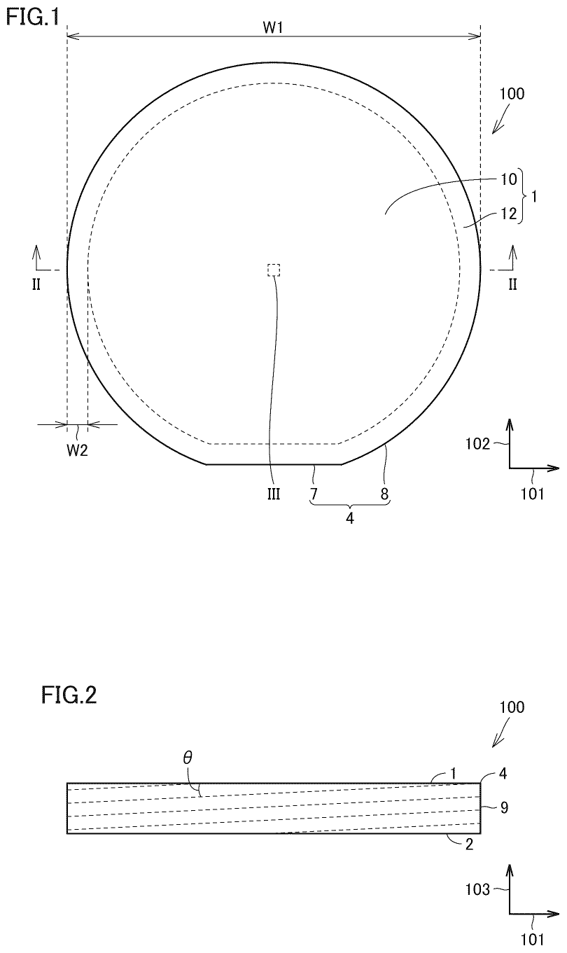

First, a configuration of a silicon carbide substrate 100 according to the present embodiment will be described. FIG. 1 is a schematic plan view showing the configuration of silicon carbide substrate 100 according to the present embodiment. FIG. 2 is a schematic cross sectional view along a line II-II of FIG. 1.

As shown in FIGS. 1 and 2, silicon carbide substrate 100 according to the present embodiment mainly has a first main surface 1, a second main surface 2, an outer peripheral edge 4, and an outer peripheral side surface 9. Second main surface 2 is located opposite to first main surface 1. Outer peripheral side surface 9 is contiguous to each of first main surface 1 and second main surface 2. Outer peripheral edge 4 is a boundary between first main surface 1 and outer peripheral side surface 9. First main surface 1 is constituted of a central portion 10 and an outer peripheral portion 12. Central portion 10 is surrounded by outer peripheral portion 12. Central portion 10 is contiguous to outer peripheral portion 12.

As shown in FIG. 1, as viewed in the direction perpendicular to first main surface 1, first main surface 1 is expanded along each of a first direction 101 and a second direction 102. As viewed in the direction perpendicular to first main surface 1, second direction 102 is a direction perpendicular to first direction 101. Outer peripheral edge 4 of first main surface 1 has, for example, an orientation flat 7 and an arc-shaped portion 8.

As shown in FIG. 1, orientation flat 7 is in the form of a straight line as viewed in the direction perpendicular to first main surface 1. Orientation flat 7 extends along first direction 101. Arc-shaped portion 8 is contiguous to orientation flat 7. Arc-shaped portion 8 has an arc shape as viewed in the direction perpendicular to first main surface 1.

First direction 101 is, for example, a <11-20> direction. First direction 101 may be, for example, a [11-20] direction. First direction 101 may be a direction obtained by projecting the <11-20> direction onto first main surface 1. From another viewpoint, it can be said that first direction 101 may be a direction including a <11-20> direction component, for example.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

First main surface 1 may be a {0001} plane or a plane inclined with respect to the {0001} plane. When first main surface 1 is inclined with respect to the {0001} plane, an inclination angle (off angle θ) thereof with respect to the {0001} plane is, for example, 1° or more and 8° or less. When first main surface 1 is inclined with respect to the {0001} plane, an inclination direction (off direction) of first main surface 1 is, for example, the <11-20> direction. Off angle θ may be, for example, 2° or more or 6° or less.

First main surface 1 has a maximum diameter W1 of 100 mm (4 inches) or more, for example. Maximum diameter W1 of first main surface 1 may be 150 mm (6 inches) or more, or 200 mm (8 inches) or more. Maximum diameter W1 of first main surface 1 is not particularly limited, but is, for example, 400 mm (16 inches) or less.

As viewed in the direction perpendicular to first main surface 1, maximum diameter W1 of first main surface 1 is the longest straight distance between two different points on outer peripheral edge 4. As viewed in the direction perpendicular to first main surface 1, outer peripheral portion 12 is a region within 3 mm from outer peripheral edge 4 of first main surface 1. From another viewpoint, it can be said that a width W2 of outer peripheral portion 12 in a direction (radial direction) extending radially from the center of first main surface 1 is 3 mm.

It should be noted that in the present specification, 4 inches mean 100 mm or 101.6 mm (4 inches×25.4 mm/inch). 6 inches mean 150 mm or 152.4 mm (6 inches×25.4 mm/inch). 8 inches mean 200 mm or 203.2 mm (8 inches×25.4 mm/inch). 16 inches mean 400 mm or 406.4 mm (16 inches×25.4 mm/inch).

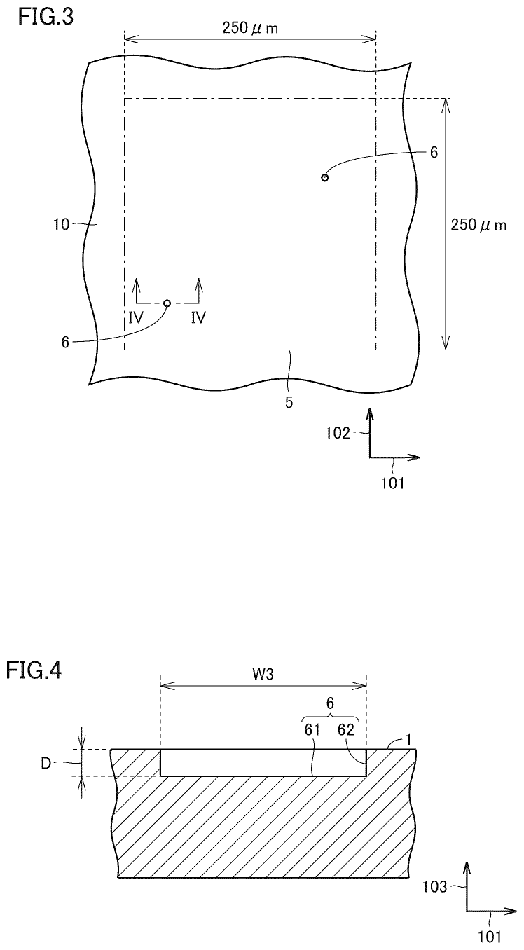

FIG. 3 is a schematic plan view showing a configuration of a region III in FIG. 1. As shown in FIG. 3, central portion 10 has a square region 5. The length of each side of square region 5 is 250 μm. As viewed in the direction perpendicular to first main surface 1, a first side of square region 5 is parallel to first direction 101, for example. As viewed in the direction perpendicular to first main surface 1, a second side of square region 5 is parallel to second direction 102, for example.

As shown in FIG. 3, a local recess 6 may be formed in central portion 10. Local recess 6 is a hole formed due to a part of silicon carbide substrate 100 being scratched off by an abrasive grain. A small number of local recesses 6 is preferable. The number of local recesses 6 in square region 5 is not particularly limited, but may be, for example, 2 or less, 1 or less, or 0.

FIG. 4 is a schematic cross sectional view along a line IV-IV of FIG. 3. As shown in FIG. 4, local recess 6 is constituted of a side surface 62 and a bottom surface 61. Side surface 62 is contiguous to first main surface 1. Bottom surface 61 is contiguous to side surface 62. In first direction 101, a length W3 of local recess 6 is substantially the same as the diameter of the abrasive grain.

Length W3 of local recess 6 is not particularly limited, but is, for example, 1 μm or more and 50 μm or less. Length W3 of local recess 6 is not particularly limited, but may be, for example, 10 μm or more or 20 μm or more. Length W3 of local recess 6 is not particularly limited, but may be, for example, 45 μm or less or 40 μm or less.

A depth D of local recess 6 is smaller than length W3 of local recess 6. Depth D of local recess 6 is not particularly limited, but may be ⅕ or less of length W3 of local recess 6, or may be 1/10 or less of length W3 of local recess 6. Depth D of local recess 6 is not particularly limited, but is, for example, 1 μm or more and 5 μm or less.

In silicon carbide substrate 100 according to the present embodiment, in any square region 5 in central portion 10, an arithmetic average height defined as Sa is 0.1 nm or less and a skewness defined as Ssk is 0 or more. Each of Sa and Ssk is used as an index for quantifying a surface roughness of silicon carbide substrate 100. When Ssk is 0, distribution of the height in the surface is symmetrical in the upward/downward direction. When Ssk is larger than 0, there are many fine protrusions in the surface. When Ssk is smaller than 0, there are many fine depressions in the surface.

The arithmetic mean height defined as Sa may be, for example, 0.06 nm or more, 0.07 nm or more, or 0.08 nm or more. The arithmetic mean height defined as Sa may be, for example, 0.95 nm or less, or 0.9 nm or less.

The skewness defined as Ssk may be, for example, 0.4 or less, 0.3 or less, or 0.25 or less. The skewness defined as Ssk may be, for example, 0.01 or more, 0.05 or more, or 0.1 or more.

In silicon carbide substrate 100 according to the present embodiment, in any square region 5 in central portion 10, the arithmetic average height defined as Sa may be 0.06 nm or more and 0.1 nm or less and the skewness defined as Ssk may be 0 or more and 0.3 or less. The arithmetic mean height defined as Sa may be 0.07 nm or more and 0.09 nm or less, and the skewness defined as Ssk may be 0.01 or more and 0.25 or less.

Next, a method of measuring each of the arithmetic mean height defined as Sa and the skewness defined as Ssk will be described.

Each of the arithmetic mean height defined as Sa and the skewness defined as Ssk can be measured, for example, by a white light interferometric microscope. As the white light interferometric microscope, BW-D507 provided by NIKON can be used, for example. The magnification of an objective lens thereof is, for example, 20 times. Sa is a parameter obtained by expanding Ra, which is a two-dimensional arithmetic mean roughness, to three dimensions. Each of Sa and Ssk is a three-dimensional surface quality parameter defined in International Standard ISO25178. A measurement region for each of Sa and Ssk is square region 5 having each side with a length of 250 μm.

### <Method of Manufacturing Silicon Carbide Substrate>

Next, a method of manufacturing silicon carbide substrate 100 according to the present embodiment will be described.

First, a crystal growth step is performed. Specifically, a silicon carbide single crystal is formed using a sublimation method. Next, the silicon carbide single crystal is cut into a plurality of silicon carbide substrates 100 by a saw wire.

Next, a double-sided mechanical polishing step is performed. Specifically, each of silicon carbide substrates 100 is disposed between a first surface plate (not shown) and a second surface plate (not shown). Next, slurry is introduced between silicon carbide substrate 100 and the first surface plate and between silicon carbide substrate 100 and the second surface plate. The slurry includes, for example, diamond abrasive grains and water. The diameter of each of the diamond abrasive grains is, for example, 1 μm or more and 3 μm or less. Thus, mechanical polishing is performed onto the both surfaces of silicon carbide substrate 100.

Next, a chemical mechanical polishing step is performed. FIG. 5 is a schematic diagram showing the step of performing chemical mechanical polishing onto silicon carbide substrate 100. As shown in FIG. 5, a chemical mechanical polishing apparatus 300 has a polishing cloth 301, a polishing head 302, a vibration acceleration sensor 303, a vacuum pump 304, and a pressure application unit 305. Polishing cloth 301 is, for example, a suede polishing cloth (G804 W) provided by Fujibo Ehime. Polishing head 302 is composed of, for example, ceramic or stainless steel. Vibration acceleration sensor 303 is attached to polishing head 302. Pressure application unit 305 is, for example, an air cylinder.

As shown in FIG. 5, in the chemical mechanical polishing step, chemical mechanical polishing is performed onto silicon carbide substrate 100 using a polishing liquid 310. Polishing liquid 310 has, for example, abrasive grains 312 and an oxidizing agent 311. Each of abrasive grains 312 is colloidal silica, for example. Oxidizing agent 311 is, for example, hydrogen peroxide water, permanganate, nitrate, hypochlorite, or the like. Polishing liquid 310 is, for example, DSC-0902 provided by Fujimi Incorporated.

In the chemical mechanical polishing step according to the present disclosure, silicon carbide substrate 100 is not attached to polishing head 302 using wax. Silicon carbide substrate 100 is directly attached to polishing head 302. Specifically, silicon carbide substrate 100 is vacuum-adsorbed to polishing head 302 using vacuum pump 304.

In the chemical mechanical polishing step according to the present disclosure, polishing head 302 is controlled to attain a small fluctuation in pressure to be applied to silicon carbide substrate 100. Specifically, the vibration of polishing head 302 is controlled such that an effective value of vibration acceleration in a frequency band of 1 kHz or less becomes 20 mG or less. Specifically, a regulator of the air cylinder may be controlled based on the vibration acceleration of polishing head 302 measured using vibration acceleration sensor 303. In this way, occurrence of local pressure fluctuation can be suppressed during the chemical mechanical polishing step.

Silicon carbide substrate 100 is disposed to face polishing cloth 301. Polishing liquid 310 including abrasive grains 312 is supplied between silicon carbide substrate 100 and polishing cloth 301. A rotation speed of polishing head 302 is, for example, 60 rpm. A rotation speed of the surface plate provided with polishing cloth 301 is, for example, 60 rpm. An average processing surface pressure F is, for example, 450 g/cm². A flow rate of the polishing liquid is 2 liters per minute, for example. In this way, silicon carbide substrate 100 (FIG. 1) according to the present embodiment is obtained.

### <Method of Manufacturing Silicon Carbide Semiconductor Device>

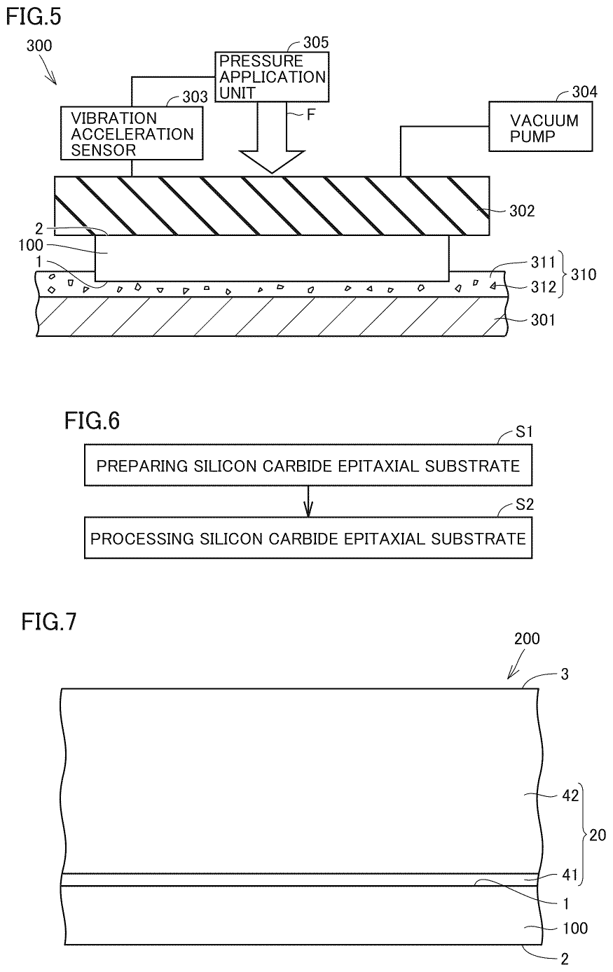

Next, a method of manufacturing a silicon carbide semiconductor device 400 according to the present embodiment will be described. FIG. 6 is a flowchart schematically showing the method of manufacturing silicon carbide semiconductor device 400 according to the present embodiment. As shown in FIG. 6, the method of manufacturing silicon carbide semiconductor device 400 according to the present embodiment mainly includes a step (S1) of preparing a silicon carbide epitaxial substrate 200 and a step (S2) of processing silicon carbide epitaxial substrate 200.

First, the step (S1) of preparing silicon carbide epitaxial substrate 200 is performed. In the step (S1) of preparing silicon carbide epitaxial substrate 200, silicon carbide substrate 100 according to the present embodiment is first prepared (see FIG. 1).

Next, a silicon carbide epitaxial layer 20 is formed on silicon carbide substrate 100. Specifically, silicon carbide epitaxial layer 20 is formed by epitaxial growth on first main surface 1 of silicon carbide substrate 100. In the epitaxial growth, for example, silane (SiH₄) and propane (C₃H₈) are each used as a source gas, and hydrogen (H₂) is used as a carrier gas. The temperature of the epitaxial growth is, for example, about 1400° C. or more and 1700° C. or less. In the epitaxial growth, an n type impurity such as nitrogen is introduced into silicon carbide epitaxial layer 20. In this way, silicon carbide epitaxial substrate 200 according to the present embodiment is prepared.

FIG. 7 is a schematic cross sectional view showing a configuration of the silicon carbide epitaxial substrate according to the present embodiment. As shown in FIG. 7, the silicon carbide epitaxial substrate according to the present embodiment has silicon carbide substrate 100 and silicon carbide epitaxial layer 20. Silicon carbide epitaxial layer 20 is provided on silicon carbide substrate 100.

Silicon carbide epitaxial layer 20 may have a buffer layer 41, a drift layer 42, and a third surface 3. Buffer layer 41 is in contact with silicon carbide substrate 100. Drift layer 42 is provided on buffer layer 41. The concentration of nitrogen included in drift layer 42 may be lower than the concentration of the nitrogen included in buffer layer 41. Third main surface 3 is constituted of drift layer 42.

Next, the step (S2) of processing silicon carbide epitaxial substrate 200 is performed. Specifically, the following processes are performed to silicon carbide epitaxial substrate 200. First, ion implantation is performed into silicon carbide epitaxial substrate 200.

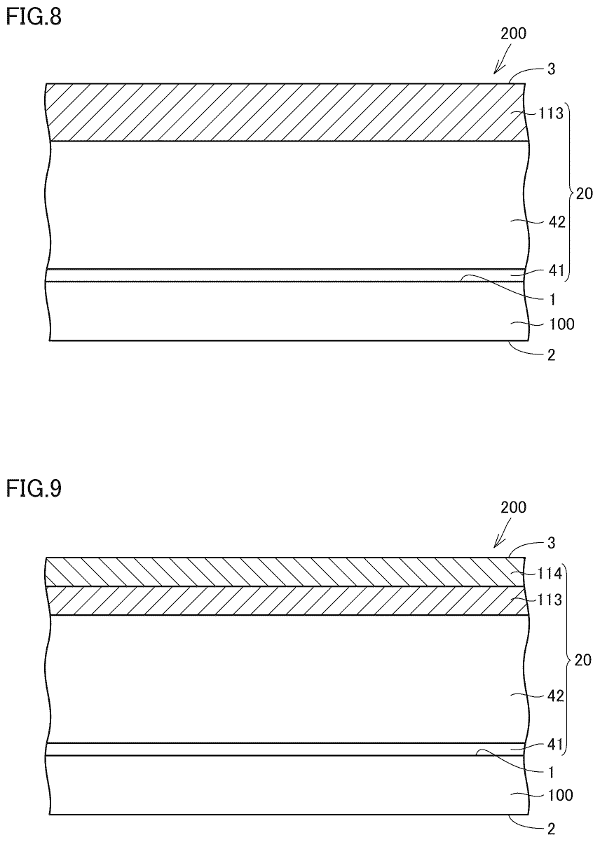

FIG. 8 is a schematic cross sectional view showing a step of forming a body region. In the step of forming the body region, ion implantation of a p type impurity such as aluminum is performed into third main surface 3 of silicon carbide epitaxial layer 20. Thus, a body region 113 having p type conductivity is formed. Portions in which no body region 113 is formed serve as drift layer 42 and buffer layer 41. The thickness of body region 113 is, for example, 0.9 μm. Silicon carbide epitaxial layer 20 includes buffer layer 41, drift layer 42, and body region 113.

Next, a step of forming a source region is performed. FIG. 9 is a schematic cross sectional view showing the step of forming the source region. Specifically, ion implantation of an n type impurity such as phosphorus is performed into body region 113. Thus, a source region 114 having n type conductivity is formed. The thickness of source region 114 is, for example, 0.4 μm. The concentration of the n type impurity included in source region 114 is higher than the concentration of the p type impurity included in body region 113.

Next, ion implantation of a p type impurity such as aluminum is performed into source region 114 so as to form a contact region 118. Contact region 118 is formed to extend through source region 114 and body region 113 and come into contact with drift layer 42. The concentration of the p type impurity included in contact region 118 is higher than the concentration of the n type impurity included in source region 114.

Next, activation annealing is performed to activate the impurities implanted by the ion implantation. A temperature of the activation annealing is, for example, 1500° C. or more and 1900° C. or less. A time of the activation annealing is, for example, about 30 minutes. An atmosphere of the activation annealing is, for example, an argon atmosphere.

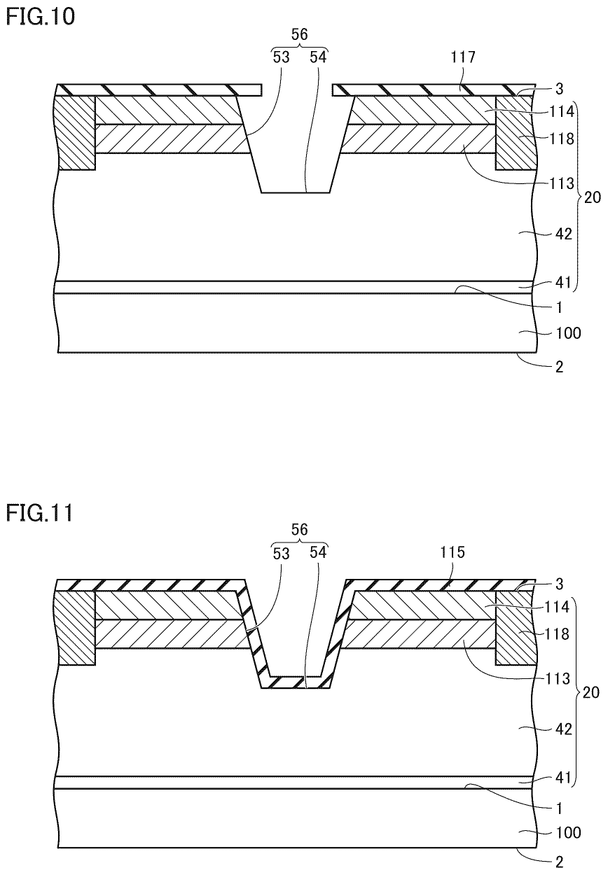

Next, a step of forming a trench in third main surface 3 of silicon carbide epitaxial layer 20 is performed. FIG. 10 is a schematic cross sectional view showing the step of forming the trench in third main surface 3 of silicon carbide epitaxial layer 20. A mask 117 provided with an opening is formed on third main surface 3 constituted of source region 114 and contact region 118. Source region 114, body region 113, and a portion of drift layer 42 are removed by etching using mask 117. As the etching method, for example, inductively coupled plasma reactive ion etching can be used. Specifically, for example, inductively coupled plasma reactive ion etching using SF₆ or a mixed gas of SF₆ and O₂ as a reaction gas is used. A recess is formed in third main surface 3 by the etching.

Next, thermal etching is performed in the recess. The thermal etching may be performed, for example, by heating in an atmosphere including a reactive gas having at least one type of halogen atom with mask 117 being formed on third main surface 3. The at least one type of halogen atom includes at least one of a chlorine (Cl) atom and a fluorine (F) atom. The atmosphere includes, for example, Cl₂, BCl₃, SF₆, or CF₄. For example, the thermal etching is performed using a mixed gas of chlorine gas and oxygen gas as a reactive gas at a heat treatment temperature of, for example, 700° C. or more and 1000° C. or less. It should be noted that the reactive gas may include a carrier gas in addition to the chlorine gas and the oxygen gas. An exemplary, usable carrier gas is nitrogen gas, argon gas, helium gas, or the like.

As shown in FIG. 10, a trench 56 is formed in third main surface 3 by thermal etching. Trench 56 is defined by a side wall surface 53 and a bottom wall surface 54. Side wall surface 53 is constituted of source region 114, body region 113, and drift layer 42. Bottom wall surface 54 is constituted of drift layer 42. Next, mask 117 is removed from third main surface 3.

Next, a step of forming a gate insulating film is performed. FIG. 11 is a schematic cross sectional view showing the step of forming the gate insulating film. Specifically, silicon carbide epitaxial substrate 200 in which trench 56 is formed in third main surface 3 is heated in an atmosphere including oxygen at a temperature of, for example, 1300° C. or more and 1400° C. or less. Thus, a gate insulating film 115 is formed in contact with drift layer 42 at bottom wall surface 54, in contact with each of drift layer 42, body region 113, and source region 114 at side wall surface 53, and in contact with each of source region 114 and contact region 118 at third main surface 3.

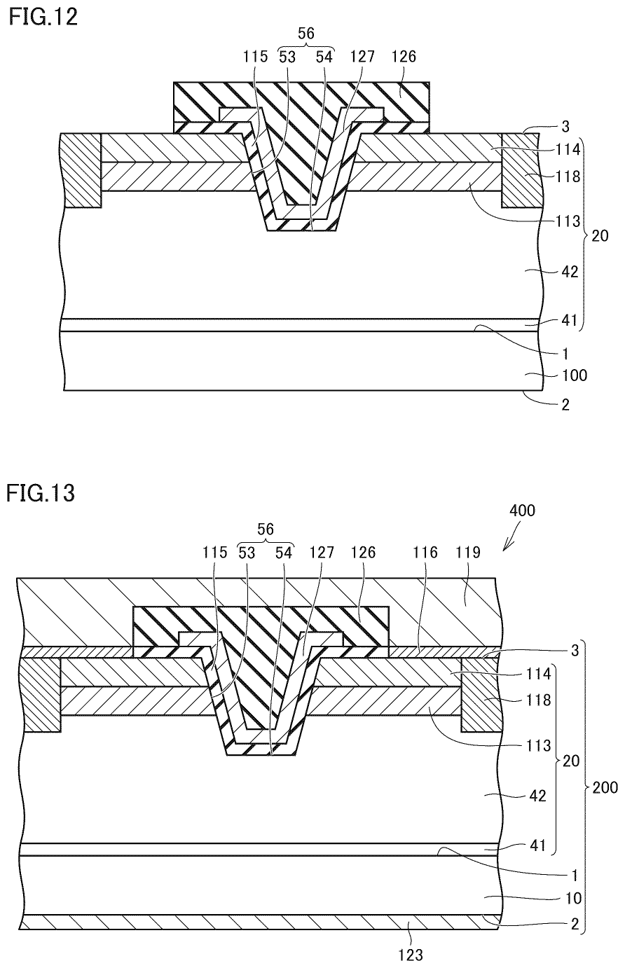

Next, a step of forming a gate electrode is performed. FIG. 12 is a schematic cross sectional view showing the step of forming the gate electrode and an interlayer insulating film. A gate electrode 127 is formed inside trench 56 so as to be in contact with gate insulating film 115. Gate electrode 127 is disposed inside trench 56, and is formed on gate insulating film 115 so as to face each of side wall surface 53 and bottom wall surface 54 of trench 56. Gate electrode 127 is formed by, for example, an LPCVD (Low Pressure Chemical Vapor Deposition) method.

Next, an interlayer insulating film 126 is formed. Interlayer insulating film 126 is formed to cover gate electrode 127 and be in contact with gate insulating film 115. Interlayer insulating film 126 is formed by, for example, a chemical vapor deposition method. Interlayer insulating film 126 is composed of, for example, a material including silicon dioxide. Next, portions of interlayer insulating film 126 and gate insulating film 115 are etched to form an opening above source region 114 and contact region 118. Thus, contact region 118 and source region 114 are exposed from gate insulating film 115.

Next, a step of forming a source electrode is performed. A source electrode 116 is formed in contact with each of source region 114 and contact region 118. Source electrode 116 is formed by, for example, a sputtering method. Source electrode 116 is composed of, for example, a material including Ti (titanium), Al (aluminum), and Si (silicon).

Next, alloying annealing is performed. Specifically, source electrode 116 in contact with each of source region 114 and contact region 118 is held at a temperature of, for example, 900° C. or more and 1100° C. or less for about 5 minutes. Thus, at least a portion of source electrode 116 is silicided. In this way, source electrode 116 in ohmic contact with source region 114 is formed. Source electrode 116 may be in ohmic contact with contact region 118.

Next, a source wiring 119 is formed. Source wiring 119 is electrically connected to source electrode 116. Source wiring 119 is formed to cover source electrode 116 and interlayer insulating film 126.

Next, a step of forming a drain electrode is performed. First, second main surface 2 of silicon carbide substrate 100 is polished. Thus, the thickness of silicon carbide substrate 100 is reduced. Next, a drain electrode 123 is formed. Drain electrode 123 is formed in contact with second main surface 2. In this way, silicon carbide semiconductor device 400 according to the present embodiment is manufactured.

FIG. 13 is a schematic cross sectional view showing a configuration of the silicon carbide semiconductor device according to the present embodiment. Silicon carbide semiconductor device 400 is, for example, a MOSFET (Metal Oxide Semiconductor Field Effect Transistor). Silicon carbide semiconductor device 400 mainly has silicon carbide epitaxial substrate 200, gate electrode 127, gate insulating film 115, source electrode 116, drain electrode 123, source wiring 119, and interlayer insulating film 126. Silicon carbide epitaxial substrate 200 has buffer layer 41, drift layer 42, body region 113, source region 114, and contact region 118. Silicon carbide semiconductor device 400 may be, for example, an IGBT (Insulated Gate Bipolar Transistor) or the like.

Next, functions and effects of silicon carbide substrate 100, silicon carbide epitaxial substrate 200, and the method of manufacturing silicon carbide semiconductor device 400 according to the present embodiment will be described.

Silicon carbide substrate 100 is required to have a very smooth main surface. As an index for surface roughness, the arithmetic mean height (Sa) is generally used. However, even when Sa in main surface 1 of silicon carbide substrate 100 is low, yield of silicon carbide semiconductor device 400 manufactured using silicon carbide substrate 100 may be low.

As a result of diligent study on a cause for the low yield of silicon carbide semiconductor device 400, the inventors have found that local recess 6, which is fine to such an extent that it does not affect Sa of main surface 1, adversely affects the yield of silicon carbide semiconductor device 400. One of causes for the low yield is considered that the thickness of the oxide film formed on local recess 6 is thin to result in decreased breakdown voltage of silicon carbide semiconductor device 400.

As a result of further study, the inventors have paid attention to such a fact that local recess 6, which is fine to such an extent that it does not affect Sa of main surface 1, is strongly correlated with the skewness defined as Ssk. Specifically, the yield of silicon carbide semiconductor device 400 can be improved by setting the arithmetic average height defined as Sa to 0.1 nm or less and the skewness defined as Ssk to 0 or more in main surface 1 of silicon carbide substrate 100.

Silicon carbide is a material having very high hardness. Therefore, when polishing silicon carbide substrate 100, a high load is applied to silicon carbide substrate 100. When silicon carbide substrate 100 is polished using a polishing liquid including abrasive grains, pressure fluctuation occurs locally due to slight vibration or the like during the application of pressure, with the result that local recess 6 may be formed in the surface of silicon carbide substrate 100. In the method of manufacturing silicon carbide substrate 100 according to the present disclosure, the chemical mechanical polishing was performed onto silicon carbide substrate 100 while suppressing the local pressure fluctuation.

As a first point of improvement, in the chemical mechanical polishing step according to the present disclosure, silicon carbide substrate 100 was directly attached to the polishing head without using wax. Typically, wax is used to attach silicon carbide substrate 100 to the polishing head, which serves as a supporting body. On this occasion, by pressing silicon carbide substrate 100, silicon carbide substrate 100 is attached to the polishing head with the wax being interposed therebetween. When pressing silicon carbide substrate 100, a foreign matter may bite into silicon carbide substrate 100 to form a recess in silicon carbide substrate 100. Since silicon carbide substrate 100 is directly attached to the polishing head without using wax in the chemical mechanical polishing step according to the present disclosure, local recess 6 can be suppressed from being formed in silicon carbide substrate 100.

As a second point of improvement, in the chemical mechanical polishing step according to the present disclosure, polishing head 302 is controlled to attain a small fluctuation in pressure to be applied to silicon carbide substrate 100. Specifically, the vibration of polishing head 302 is controlled such that the effective value of the vibration acceleration in the frequency band of 1 kHz or less becomes 20 mG or less. Thus, occurrence of local pressure fluctuation can be suppressed during the chemical mechanical polishing step. As a result, local recess 6 can be suppressed from being formed in silicon carbide substrate 100.

In silicon carbide substrate 100 according to the present embodiment, the arithmetic average height defined as Sa is 0.1 nm or less and the skewness defined as Ssk is 0 or more. Thus, the yield of silicon carbide semiconductor device 400 can be improved.

In silicon carbide substrate 100 according to the present embodiment, the skewness defined as Ssk may be 0.4 or less. Thus, the yield of silicon carbide semiconductor device 400 can be further improved.

In silicon carbide substrate 100 according to the present embodiment, the skewness defined as Ssk may be 0.3 or less. Thus, the yield of silicon carbide semiconductor device 400 can be further improved.

In silicon carbide substrate 100 according to the present embodiment, the arithmetic average height defined as Sa may be 0.06 nm or more. Thus, the yield of silicon carbide semiconductor device 400 can be further improved.

In silicon carbide substrate 100 according to the present embodiment, the arithmetic average height defined as Sa may be 0.06 nm or more and the skewness defined as Ssk may be 0.3 or less. Thus, the yield of silicon carbide semiconductor device 400 can be further improved.

In silicon carbide substrate 100 according to the present embodiment, the maximum diameter of the main surface may be 150 mm or more. Thus, even when silicon carbide substrate 100 having such a large diameter is used, the yield of silicon carbide semiconductor device 400 can be improved.

### EXAMPLES

Next, examples will be described. Each of silicon carbide substrates 100 according to samples 1-1 to 1-5 was manufactured using a chemical mechanical polishing step of a group G1. Each of silicon carbide substrates 100 according to samples 2-1 to 2-4 was manufactured using a chemical mechanical polishing step of a group G2. Each of silicon carbide substrates 100 according to samples 3-1 to 3-12 was manufactured using a chemical mechanical polishing step of a group G3.

In the chemical mechanical polishing step of each of groups G1, G2, and G3, each of abrasive grains 312 was colloidal silica. Polishing liquid 310 was DSC-0902 provided by Fujimi Incorporated. A rotation speed of polishing head 302 was 60 rpm. A rotation speed of the surface plate provided with polishing cloth 301 was 60 rpm.

An average processing surface pressure F was 450 g/cm². A flow rate of the polishing liquid was 2 liters per minute.

In the chemical mechanical polishing step of group G1, silicon carbide substrate 100 was attached to polishing head 302 using wax. On the other hand, in each of the chemical mechanical polishing steps of groups G2 and G3, silicon carbide substrate 100 was directly attached to polishing head 302 without using wax.

In each of the chemical mechanical polishing steps of groups G1 and G2, control for vibration of polishing head 302 was not performed. On the other hand, in the chemical mechanical polishing step of group G3, control for vibration of polishing head 302 was performed. Specifically, the vibration of polishing head 302 was controlled such that the effective value of the vibration acceleration in the frequency band of 1 kHz or less became 20 mG or less.

Next, each of Sa and Ssk was measured in central portion 10 of silicon carbide substrate 100 according to each of samples 1-1 to 3-12. Each of Sa and Ssk was measured using a white light interferometric microscope (BW-D507 provided by Nikon). A measurement region for each of Sa and Ssk was square region 5 having each side with a length of 250 μm. A MOSFET was produced using each of silicon carbide substrates 100 according to samples 1-1 to 3-12, and a breakdown voltage failure ratio of the MOSFET was obtained.

TABLE 1

| | | | | | | Breakdown |
|---|---|---|---|---|---|---|
| | | | Control | | | Voltage |
| | Sample | Adhesion | for | Sa | | Failure Ratio |
| Group | Number | by Wax | Vibration | [nm] | Ssk | [%] |
| G1 | 1-1 | Performed | Not | 0.128 | −0.04 | 33 |
| | 1-2 | | Performed | 0.133 | 0.045 | 34 |
| | 1-3 | | | 0.13 | 0.297 | 33 |
| | 1-4 | | | 0.117 | 0.081 | 29 |
| | 1-5 | | | 0.133 | −0.092 | 35 |

Table 1 shows Sa and Ssk in central portion 10 of silicon carbide substrate 100 according to each of samples 1-1 to 1-5, and the breakdown voltage failure ratio of the MOSFET manufactured using silicon carbide substrate 100. Sa was 0.117 nm or more and 0.133 nm or less. Ssk was −0.092 or more and 0.297 or less. The breakdown voltage failure ratio was 29% or more and 35% or less.

TABLE 2

| | | | | | | Breakdown |
|---|---|---|---|---|---|---|
| | | | Control | | | Voltage |
| | Sample | Adhesion | for | Sa | | Failure Ratio |
| Group | Number | by Wax | Vibration | [nm] | Ssk | [%] |
| G2 | 2-1 | Not | Not | 0.095 | −0.183 | 27 |
| | 2-2 | Performed | Performed | 0.078 | −0.427 | 31 |
| | 2-3 | | | 0.088 | −0.105 | 27 |
| | 2-4 | | | 0.091 | −0.015 | 27 |

Table 2 shows Sa and Ssk in central portion 10 of silicon carbide substrate 100 according to each of samples 2-1 to 2-4, and the breakdown voltage failure ratio of the MOSFET manufactured using silicon carbide substrate 100. Sa was 0.078 nm or more and 0.095 nm or less. Ssk was −0.427 or more and −0.015 or less. The breakdown voltage failure ratio was 27% or more and 31% or less.

TABLE 3

| | | | | | | Breakdown |
|---|---|---|---|---|---|---|
| | | | Control | | | Voltage |
| | Sample | Adhesion | for | Sa | | Failure Ratio |
| Group | Number | by Wax | Vibration | [nm] | Ssk | [%] |
| G3 | 3-1 | Not | Performed | 0.087 | 0.229 | 21 |
| | 3-2 | Performed | | 0.085 | 0.189 | 20 |
| | 3-3 | | | 0.094 | 0.122 | 21 |
| | 3-4 | | | 0.092 | 0.027 | 22 |
| | 3-5 | | | 0.092 | 0.174 | 21 |
| | 3-6 | | | 0.079 | 0.106 | 20 |
| | 3-7 | | | 0.095 | 0.181 | 19 |
| | 3-8 | | | 0.089 | 0.065 | 21 |
| | 3-9 | | | 0.087 | 0.101 | 21 |
| | 3-10 | | | 0.081 | 0.237 | 19 |
| | 3-11 | | | 0.083 | 0.215 | 20 |
| | 3-12 | | | 0.083 | 0.001 | 22 |

Table 3 shows Sa and Ssk in central portion 10 of silicon carbide substrate 100 according to each of samples 3-1 to 3-12, and the breakdown voltage failure ratio of the MOSFET manufactured using silicon carbide substrate 100. Sa was 0.079 nm or more and 0.095 nm or less. Ssk was 0.001 or more and 0.237 or less. The breakdown voltage failure ratio was 19% or more and 22% or less.

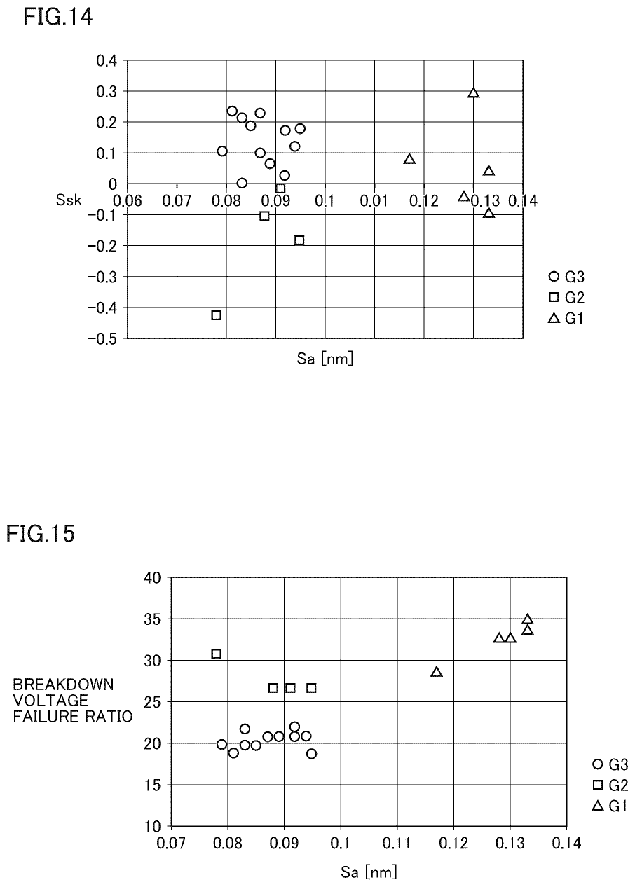

FIG. 14 is a diagram showing a relation between Sa and Ssk. As shown in FIG. 14, in silicon carbide substrate 100 manufactured using the chemical mechanical polishing step of group G2, Sa is low and Ssk is less than 0. On the other hand, in silicon carbide substrate 100 manufactured using the chemical mechanical polishing step of group G3, Sa is low and Ssk is 0 or more.

FIG. 15 is a diagram showing a relation between Sa and the breakdown voltage failure ratio. As shown in FIG. 15, the breakdown voltage failure ratio of silicon carbide semiconductor device 400 manufactured using silicon carbide substrate 100 manufactured using the chemical mechanical polishing step of group G2 was a relatively high. On the other hand, the breakdown voltage failure ratio of silicon carbide semiconductor device 400 manufactured using silicon carbide substrate 100 manufactured using the chemical mechanical polishing step of group G3 was significantly low. In view of the above results, it was confirmed that the breakdown voltage failure ratio of silicon carbide semiconductor device 400 can be significantly reduced by setting Sa to 0.1 nm or less and setting Ssk to 0 or more.

The present disclosure includes the following embodiments.

### Supplementary Note 1

A silicon carbide substrate comprising a main surface, wherein
the main surface is constituted of an outer peripheral portion within 3 mm from an outer peripheral edge of the main surface and a central portion surrounded by the outer peripheral portion,
in any square region in the central portion, an arithmetic mean height defined as Sa is 0.1 nm or less and a skewness defined as Ssk is 0 or more, and a length of each side of the square region is 250 μm.

### Supplementary Note 2

The silicon carbide substrate according to supplementary note 1, wherein the skewness defined as Ssk is 0.4 or less.

### Supplementary Note 3

The silicon carbide substrate according to supplementary note 1, wherein the skewness defined as Ssk is 0.3 or less.

### Supplementary Note 4

The silicon carbide substrate according to any one of supplementary notes 1 to 3, wherein the arithmetic mean height defined as Sa is 0.06 nm or more.

### Supplementary Note 5

The silicon carbide substrate according to supplementary note 1, wherein the arithmetic mean height defined as Sa is 0.06 nm or more and the skewness defined as Ssk is 0.3 or less.

### Supplementary Note 6

The silicon carbide substrate according to any one of supplementary notes 1 to 3, wherein a maximum diameter of the main surface is 150 mm or more.

### Supplementary Note 7

A silicon carbide epitaxial substrate comprising:
the silicon carbide substrate according to any one of supplementary notes 1 to 3; and
a silicon carbide epitaxial layer provided on the silicon carbide substrate.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface (main surface); 2: second main surface; 3: third main surface; 4: outer peripheral edge; 5: square region; 6: local recess; 7: orientation flat; 8: arc-shaped portion; 9: outer peripheral side surface; 10: central portion; 12: outer peripheral portion; 20: silicon carbide epitaxial layer; 41: buffer layer; 42: drift layer; 53: side wall surface; 54: bottom wall surface; 56: trench; 61: bottom surface; 62: side surface; 100: silicon carbide substrate; 101: first direction; 102: second direction; 113: body region; 114: source region; 115: gate insulating film; 116: source electrode; 117: mask; 118: contact region; 119: source wiring; 123: drain electrode; 126: interlayer insulating film; 127: gate electrode; 200: silicon carbide epitaxial substrate; 300: chemical mechanical polishing apparatus; 301: polishing cloth; 302: polishing head; 303: vibration acceleration sensor; 304: vacuum pump; 305: pressure application unit; 310: polishing liquid; 311: oxidizing agent; 312: abrasive grain; 400: silicon carbide semiconductor device; D: depth; F: average processing surface pressure; W1: maximum diameter; W2: width; W3: length; 0: off angle.

1. A silicon carbide substrate comprising a main surface, wherein
the main surface is constituted of an outer peripheral portion within 3 mm from an outer peripheral edge of the main surface and a central portion surrounded by the outer peripheral portion,
in any square region in the central portion, an arithmetic mean height defined as Sa is 0.1 nm or less and a skewness defined as Ssk is 0 or more, and
a length of each side of the square region is 250 μm.

2. The silicon carbide substrate according to claim 1, wherein the skewness defined as Ssk is 0.4 or less.

3. The silicon carbide substrate according to claim 1, wherein the skewness defined as Ssk is 0.3 or less.

4. The silicon carbide substrate according to of claim 1, wherein the arithmetic mean height defined as Sa is 0.06 nm or more.

5. The silicon carbide substrate according to claim 1, wherein the arithmetic mean height defined as Sa is 0.06 nm or more and the skewness defined as Ssk is 0.3 or less.

6. The silicon carbide substrate according to claim 1, wherein a maximum diameter of the main surface is 150 mm or more.

7. A silicon carbide epitaxial substrate comprising:
the silicon carbide substrate according to claim 1; and
a silicon carbide epitaxial layer provided on the silicon carbide substrate.

8. A method of manufacturing a silicon carbide semiconductor device, the method comprising:
preparing the silicon carbide epitaxial substrate according to claim 7; and
processing the silicon carbide epitaxial substrate.
